(19) United States
(12) Patent Application Publication
(10) Pub. No.: US 2026/0165042 A1
(43) Pub. Date: Jun. 11, 2026

(54) METHOD FOR MANUFACTURING SEMICONDUCTOR STRUCTURE

(71) Applicant: NANYA TECHNOLOGY CORPORATION, New Taipei City (TW)

(72) Inventor: Cheng-Wei CHIU, New Taipei City (TW)

(21) Appl. No.: 18/977,867

(22) Filed: Dec. 11, 2024

(51) Int. Cl. H01L 21/3205; H01L 21/28; H01L 21/311; H01L 21/321

(52) U.S. Cl. CPC H10P 14/416; H10D 64/01328; H10P 14/6316; H10P 50/73

(57) ABSTRACT

A method for manufacturing a semiconductor structure is provided. A substrate is recessed from an upper surface toward a lower surface to form a trench. A semiconductor material is filled in the trench. A patterned metal layer is formed on the semiconductor material and a patterned hard mask is formed on the patterned metal layer. A portion of the semiconductor material is etched by using the patterned metal layer as a mask, in which a remaining portion of the semiconductor material includes a first portion and a second portion below the first portion, and the second portion is wider than the first portion. A passivation layer is formed on a sidewall of the first portion. The passivation layer is removed and the second portion of the remaining portion of the semiconductor material is etched by using the patterned metal layer as a mask, thereby forming a semiconductor layer.

### BACKGROUND

### FIELD OF INVENTION

The present disclosure relates to a method for manufacturing a semiconductor structure.

### DESCRIPTION OF RELATED ART

Semiconductor devices are beneficial in the electronic industry because of their small size, multi-functionality, and low fabrication cost. However, the semiconductor devices are being highly integrated with the remarkable development of the electronic industry. Line widths of patterns of semiconductor devices are being reduced for high integration thereof.

### SUMMARY

One aspect of the present disclosure is to provide a method for manufacturing a semiconductor structure. The method includes the following steps. A substrate is recessed from an upper surface of the substrate toward a lower surface of the substrate to form a trench. A semiconductor material is filled in the trench. A patterned metal layer is formed on the semiconductor material and a patterned hard mask is formed on the patterned metal layer. A portion of the semiconductor material is etched by using the patterned metal layer and the patterned hard mask as a first etching mask, in which a remaining portion of the semiconductor material includes a first portion and a second portion below the first portion, and the second portion is wider than the first portion. A passivation layer is formed on a sidewall of the first portion. The passivation layer is removed and the second portion of the remaining portion of the semiconductor material is etched by using the patterned metal layer and the patterned hard mask as a second etching mask, thereby forming a semiconductor layer.

According to one or more embodiments, the method further includes forming the passivation layer on the sidewall of the first portion includes reacting a nitrogen gas with the first portion.

According to one or more embodiments, the passivation layer includes nitride.

According to one or more embodiments, a thickness of the passivation layer is from about 2.0 nm to about 5.0 nm.

According to one or more embodiments, a height of the first portion of the semiconductor material is at least greater than half of a total height of the semiconductor material.

According to one or more embodiments, the semiconductor layer has a uniform width.

According to one or more embodiments, a width of the semiconductor layer is the same with a width of the patterned metal layer.

According to one or more embodiments, the method further includes before filling the semiconductor material in the trench, conformally forming an insulating layer in the trench and on the upper surface of the substrate.

According to one or more embodiments, the method further includes a spacer is formed on sidewalls of the semiconductor layer, the patterned metal layer, and the patterned hard mask.

According to one or more embodiments, the spacer is in direct contact with the semiconductor layer and is in direct contact with the insulating layer in the trench.

Another aspect of the present disclosure is to provide a method for manufacturing a semiconductor structure. The method includes the following steps. A substrate is recessed from an upper surface of the substrate toward a lower surface of the substrate to form a first trench. A semiconductor material is filled in the first trench. A patterned metal layer is formed on the semiconductor material and a patterned hard mask is formed on the patterned metal layer, in which the semiconductor material includes a first part covered by the patterned metal layer and the patterned hard mask and a second part next to the first part. The second part of the semiconductor material is partially removed to form a second trench. A passivation layer is formed to cover a sidewall of the first part. The passivation layer and the second part of the semiconductor material are removed to form a third trench next to the first part of the semiconductor material.

According to one or more embodiments, the method further includes forming the passivation layer to cover the sidewall of the first part includes reacting a nitrogen gas with the first part.

According to one or more embodiments, the nitrogen gas reacts with the first part is performed under a temperature of 50°C to 70°C.

According to one or more embodiments, the passivation layer includes nitride.

According to one or more embodiments, a thickness of the passivation layer is from about 2.0 nm to about 5.0 nm.

According to one or more embodiments, a depth of the second trench is at least greater than half of a depth of the third trench.

According to one or more embodiments, the third trench has a uniform width.

According to one or more embodiments, the method further includes forming a spacer in the third trench.

According to one or more embodiments, the method further includes before filling the semiconductor material in the first trench, conformally forming an insulating layer in the first trench and on the upper surface of the substrate.

According to one or more embodiments, the insulating layer is exposed from the third trench.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is an arrangement diagram of a semiconductor structure according to some embodiments of the present disclosure.

FIG. 2 to FIG. 5 are cross-sectional views illustrating different steps of a method of manufacturing a semiconductor structure according to some embodiments of the present disclosure.

FIG. 6 is a cross-sectional view illustrating a certain step of a method of manufacturing a semiconductor structure according to a comparative example of the present disclosure.

FIG. 7 to FIG. 12 are cross-sectional views illustrating different steps of a method of manufacturing a semiconductor structure according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

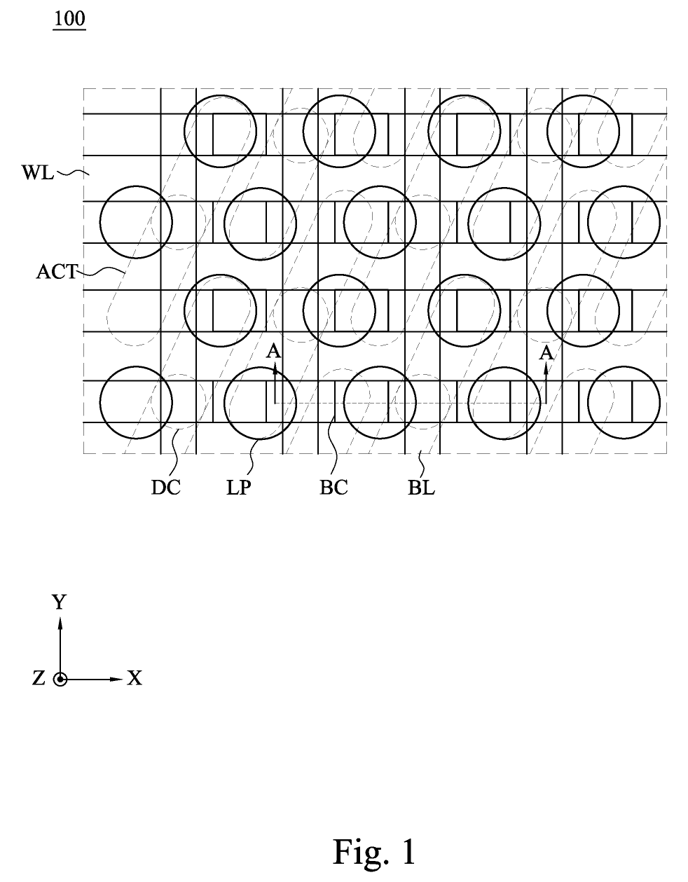

Referring to FIG. 1, FIG. 1 is an arrangement diagram of a semiconductor device 100 according to some embodiments of the present disclosure. The semiconductor device 100 may include a plurality of active areas ACT. The active area ACT has a short axis and a long axis. In some embodiment, the long axis of the active area ACT may extend in a diagonal axis with respect to an X axis.

A plurality of word lines WL may be configured across the active areas ACT and extend along the X axis. The word line WL is in parallel to each other. Additionally, the word line WL may be spaced apart from each other at substantially equal intervals.

A plurality of bit lines BL may be arranged above the word lines WL and may extend along a Y axis. Similarly, the lines BL is in parallel to each other. In addition, the bit line BL can be connected to the active area ACT through a direct contact DC. One active area ACT may be electrically connected to one direct contact DC.

A plurality of buried contacts BC may be formed between two adjacent bit lines BL. In some embodiments, the buried contacts BC may be spaced apart from each other along the Y axis. The buried contact BC may electrically connect a lower electrode of the capacitor (not shown) to a corresponding active area ACT. One active area ACT may be electrically connected to two buried contacts BC.

A plurality of landing pads LP may be disposed above the buried contacts BC and overlap at least a portion of a corresponding bit line BL. The landing pad may electrically connect the buried contact BC. Also, the landing pad LP may also electrically connect the lower electrode of the capacitor (not shown) to a corresponding active area ACT. In another words, the lower electrode of the capacitor (not shown) may be electrically connected to a corresponding active area ACT through a corresponding buried contact BC and a corresponding landing pad LP.

In some embodiments, one buried contact BC and one landing pad LP may collectively be referred to as a contact plug, and may be respectively referred to as a first contact plug (BC) and a second contact plug (LP).

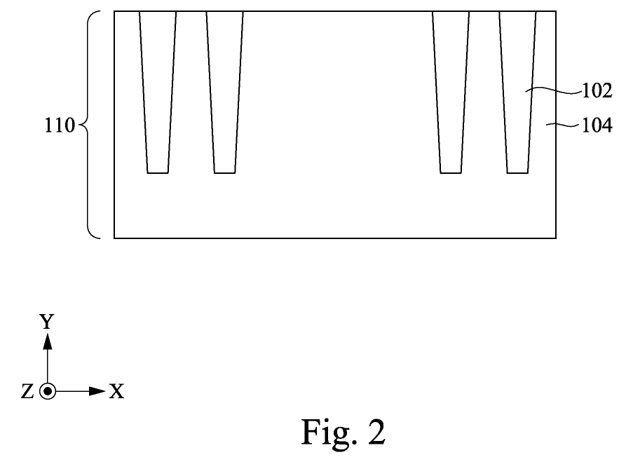

FIG. 2 to FIG. 5 and FIG. 7 to FIG. 12 are cross-sectional views illustrating different steps of a method of manufacturing a semiconductor structure (e.g., semiconductor structure 100) in accordance with some embodiments of the present disclosure. The cross-section views of FIG. 2 to FIG. 5 and FIG. 7 to FIG. 12 are based on a reference cross-sectional view taken along line A-A shown in FIG. 1.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

Referring to FIG. 2, a substrate 110 is received. To be specific, the substrate 110 includes a plurality of isolation areas 102 and a plurality of active areas 104 (as the active areas ACT in FIG. 1). The active areas 104 are spaced apart by the isolation areas 102.

The substrate 110 may include, for example, silicon (e.g., crystalline silicon, polycrystalline silicon, or amorphous silicon). In some embodiments, the substrate 110 may include compound semiconductor such as gallium arsenic, silicon carbide, indium phosphide, indium arsenide and the like. In some embodiments, the substrate 110 may include other elementary semiconductor such as germanium. In some embodiments, the substrate 110 may include an alloy semiconductor such as silicon germanium, silicon germanium carbide, gallium indium phosphide and the like. Further, the substrate 110 may optionally include a semiconductor-on-insulator (SOl) structure.

The isolation areas 102 may be formed through a shallow trench isolation (STI) process. The isolation areas 102 may include, for example, a material including at least one of silicon oxide, silicon nitride, and silicon oxynitride. The isolation areas 102 may be a single layer including one kind of insulator, a double layer including two kinds of insulators, or a multilayer including a combination of at least three kinds of insulators. For example, the isolation areas 102 may include silicon oxide and silicon nitride. For another example, the isolation areas 102 may include a triple layer including silicon oxide, silicon nitride, and silicon oxynitride.

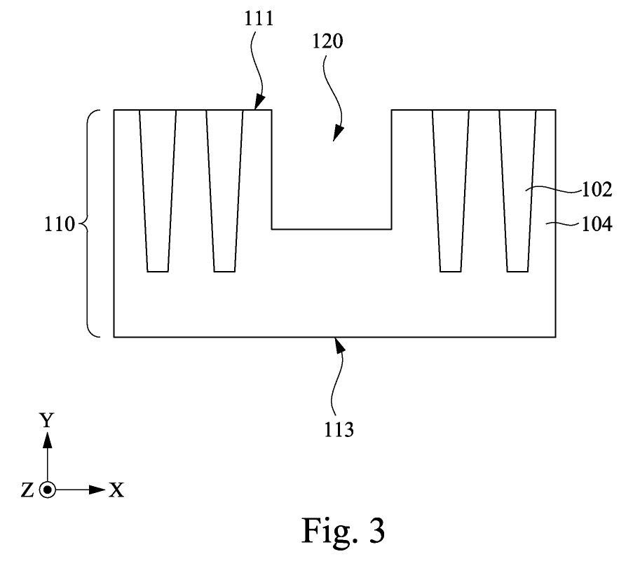

Referring to FIG. 3, the substrate 110 is recessed from an upper surface 111 of the substrate 110 toward a lower surface 113 of the substrate 110 to form a trench 120. It should be noted that the trench 120 do not penetrate the substrate 110.

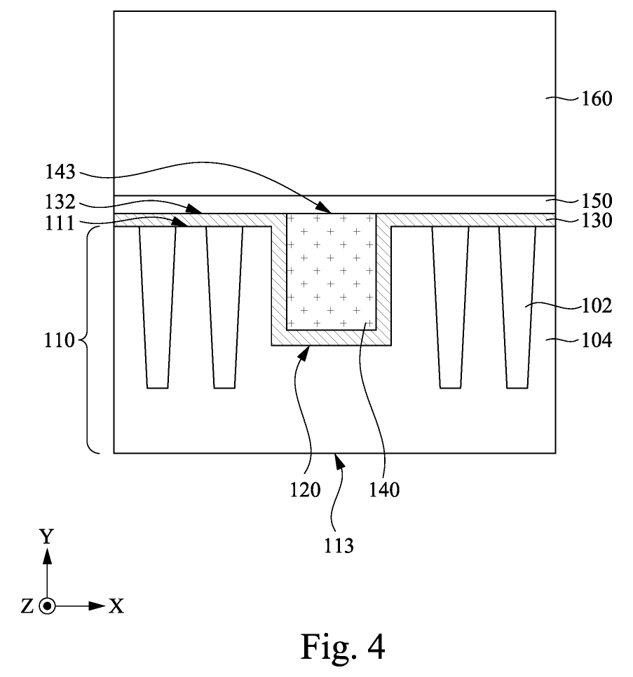

Referring to FIG. 4, an insulating layer 130 is first formed conformally in the trench 120 and on the upper surface 111 of the substrate 110. To be specific, the insulating layer 130 covers sidewalls and the bottom of the trench 120. That is to say, the insulating layer 130 does not fill up the trench 120. In some embodiments, the insulating layer 130 may be made of any suitable dielectric material, such as silicon oxide, boro-phospho silicate glass (BPSG), or tetraethyl orthosilicate (TEOS), but the present disclosure is not limited to the above materials.

Referring to FIG. 4, a semiconductor material 140 is then filled in the trench 120. More specifically, the semiconductor material 140 is formed on the insulating layer 130 within the trench 120. In other words, the semiconductor material 140 is filled up the remaining space within the trench 120. In some embodiments, a top surface 143 of the semiconductor material 140 is leveled with a top surface 132 of the insulating layer 130 disposed on the upper surface 111 of the substrate 110. In some embodiment, the semiconductor material 140 includes polysilicon. In some embodiment, the semiconductor material 140 may be doped.

Referring to FIG. 4, a metal layer 150 is next formed on the insulating layer 130 and the semiconductor material 140. More specifically, the metal layer 150 fully covers the insulating layer 130 and the semiconductor material 140. In some embodiments, the metal layer 150 may include tungsten, copper, aluminum, tantalum, titanium, and/or a combination thereof.

Referring to FIG. 4, a hard mask 160 continuous to be formed on the metal layer 150. More specifically, the hard mask 160 fully covers the metal layer 150. In some embodiments, the hard mask 160 may include a dielectric material such as, but not limited to, silicon nitride. In some embodiments, a thickness (e.g., a height along the Z axis) of the hard mask 160 may be greater than that of the metal layer 150.

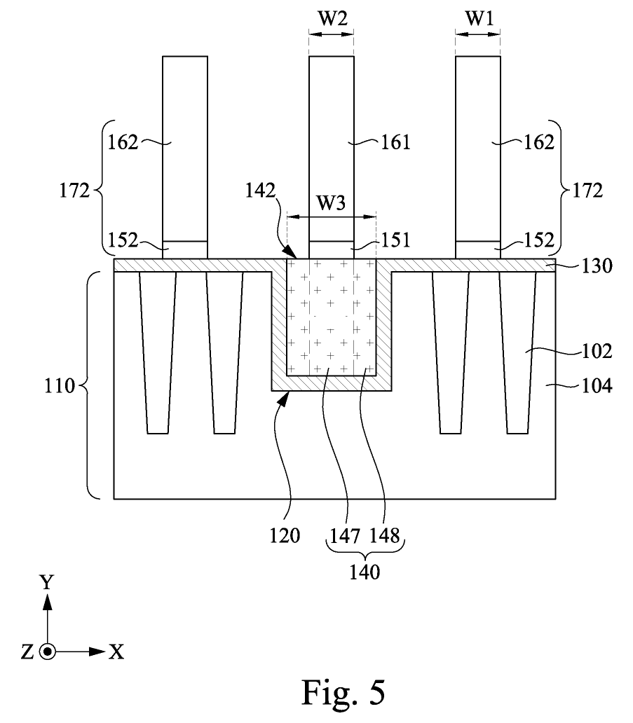

Referring to FIG. 5, the metal layer 150 and the hard mask 160 are patterned to form a first patterned metal layer 152 disposed on the insulating layer 130, a second patterned metal layer 151 disposed on the semiconductor material 140, a first patterned hard mask 162 disposed on the first patterned metal layer 152, and a second patterned hard mask 161 disposed on the second patterned metal layer 151. To be specific, the first patterned metal layer 152 is in direct contact with the insulating layer 130 disposed on the upper surface 111 of the substrate 110. In some embodiments, the first patterned metal layer 152 and the first patterned hard mask 162 have a uniform and the same widths W1. The first patterned metal layer 152 and the first patterned hard mask 162 constitute a first bit line structure 172.

Referring to FIG. 5, the second patterned metal layer 151 is in direct contact with the semiconductor material 140 within the trench 120. In some embodiments, the second patterned metal layer 151 and the second patterned hard mask 161 have a uniform and the same widths W2. It should be understood that a width W2 of the second patterned metal layer 151 is smaller than a width W3 of the semiconductor material 140. That is to say the second patterned metal layer 151 only covers a portion of the top surface 143 of the semiconductor material 140. In other words, a portion of the top surface 143 of the semiconductor material 140 is exposed after forming the second patterned metal layer 151 and the second patterned hard mask 161. On the other hands, the semiconductor material 140 may include a first part 147 covered by the second patterned metal layer 151 and the second patterned hard mask 161 and a second part 148 next to the first part. That is to say that a vertical projection of the first part 147 on the substrate 110 overlaps a vertical projection of the second patterned metal layer 151 on the substrate 110.

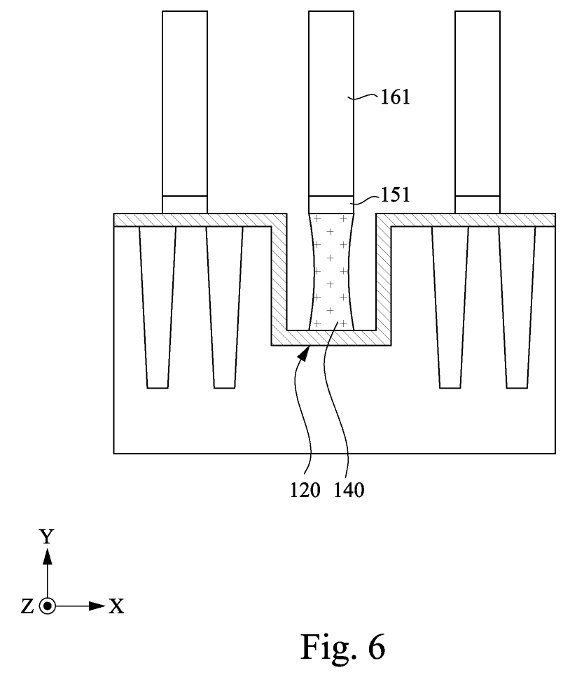

FIG. 6 is a cross-sectional view illustrating a certain step of a method of manufacturing a semiconductor structure according to a comparative example of the present disclosure. The semiconductor material would be etched in one step to form a semiconductor layer 240 as shown in FIG. 6. However, the semiconductor layer 240 is prone to necking problem, as shown in FIG. 6. It should be understood that one of the challenges faced in etching is the ever-increasing aspect ratio needed to meet design requirements, especially for ultra-high density structures. Therefore, a difficulty during high aspect ratio (HAR) etching is twisting and or distortion, which is generally defined as deviations of location, orientation, shape, and size near the bottom of a feature from the pattern defined by the mask on the top of the feature. For example, the semiconductor layer 240 obtained after etching has an undesirable “necking” or “footing” profile. The “necking” or “footing” profile would further affect the difference in the critical dimension (CD) of the product, and increase the risk of high impedance or pattern collapse in the subsequent process.

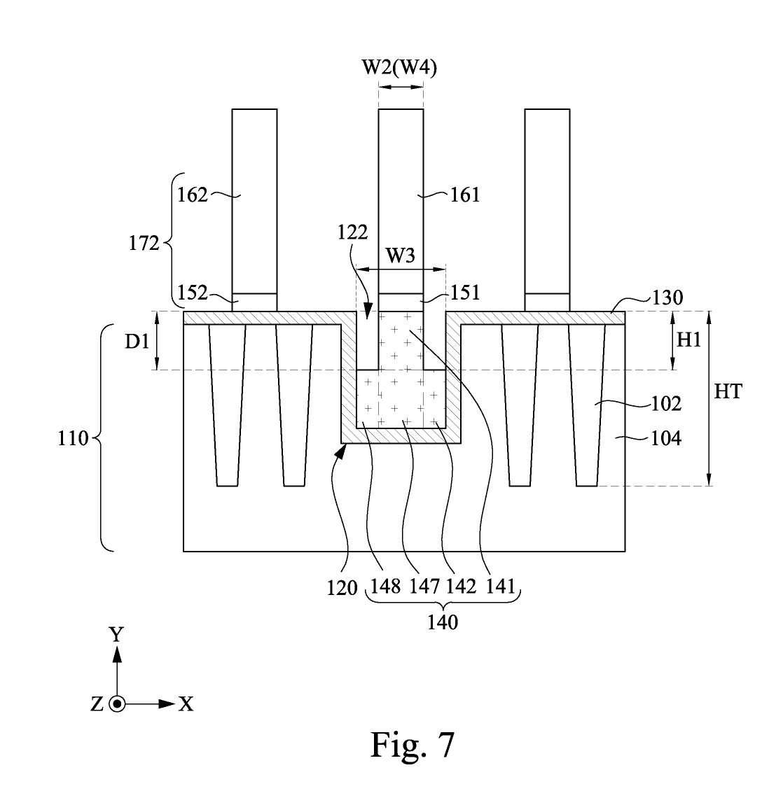

Therefore, the following etching step is used to reduce the possibility of occurrence of the “necking” or “footing” profile. FIG. 7 to FIG. 12 are cross-sectional views illustrating different steps of a method of manufacturing a semiconductor structure according to some embodiments of the present disclosure. FIG. 7 continues the process step of FIG. 5. Referring to FIG. 7, a portion of the semiconductor material 140 is etched by using the second patterned metal layer 151 and the second patterned hard mask 161 as a first etching mask so that a remaining portion of the semiconductor material 140 includes a first portion 141 and a second portion 142 below the first portion 141, and the second portion 142 is wider than the first portion 141. To be specific, a width W4 of the first portion 141 of the semiconductor material 140 is the same with W2 a width of the second patterned metal layer 151. A width of the second portion 142 is still W3. That is to say the width W3 of the second portion 142 is greater than the width W4 of the first portion 141. In some embodiments, a height H1 of the first portion 141 of the semiconductor material 140 is at least greater than half a total height HT of the semiconductor material 140. In this way, excessive side-etching of the semiconductor material 140 may be prevented.

In other words, the second part 148 of the semiconductor material 140 is partially removed to form a second trench 122. The second trench 122 does not penetrate the semiconductor material 140. The second trench 122 surrounds the first part 147 of the semiconductor material 140. In some embodiments, the second trench 122 has a depth D1.

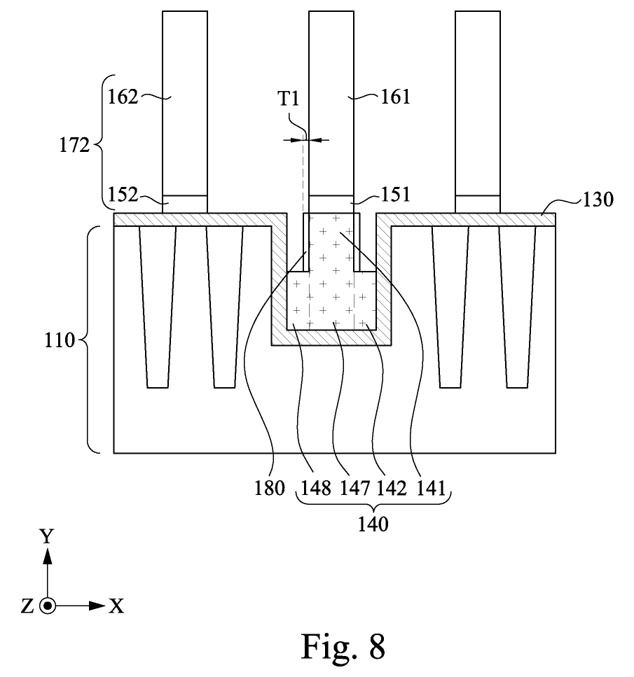

Referring to FIG. 8, a passivation layer 180 is then formed on a sidewall of the first portion 141 of the semiconductor material 140. In other words, the passivation layer 180 is then formed to cover a sidewall of the first part 147 of the semiconductor material 140. In some embodiments, nitrogen gas reacts with the surface of the first portion 141 of the semiconductor material 140, so that the passivation layer 180 is generated on the sidewall of the first portion 141. In other words, nitrogen gas reacts with the surface of the first part 147 of the semiconductor material 140, so that the passivation layer 180 is generated on the sidewall of the first part 147. In some embodiments, the passivation layer 180 includes nitride, such as silicon nitride. In some embodiments, a thickness T1 of the passivation layer 180 is from about 2.0 nm to about 5.0 nm, such as 2.2 nm, 2.4 nm, 2.6 nm, 2.8 nm, 3.0 nm, 3.2 nm, 3.4 nm, 3.6 nm, 3.8 nm, 4.0 nm, 4.2 nm, 4.4 nm, 4.6 nm, or 4.8 nm. In some embodiments, the nitrogen gas reacts with the first part 147 (or the first portion 141) is performed under a temperature of 50°C to 70°C.

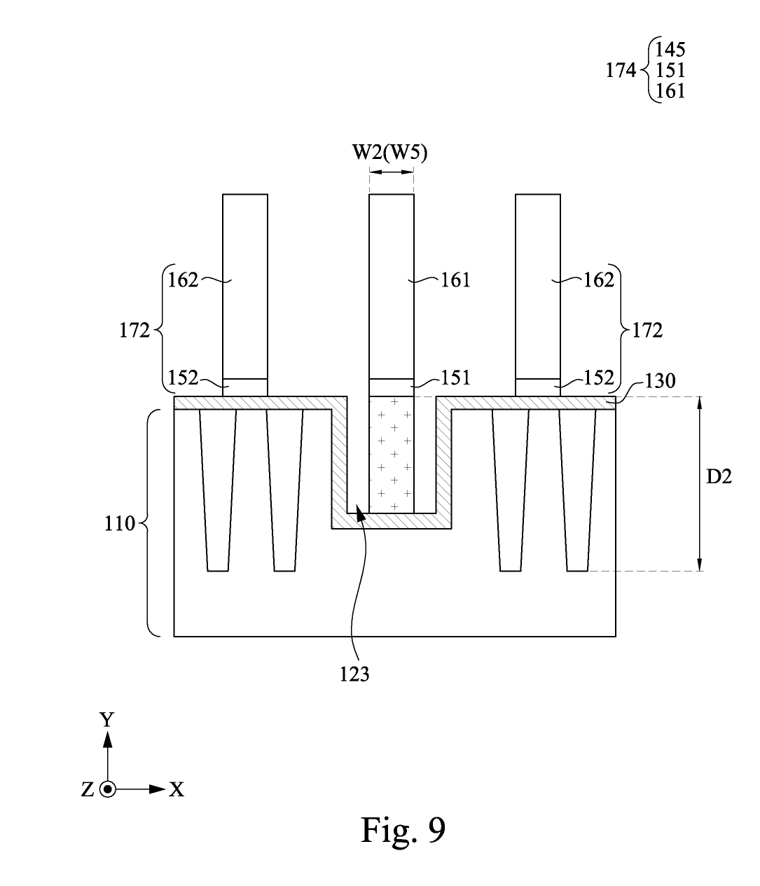

Referring to FIG. 9, the passivation layer 180 is removed and the second portion 142 of the remaining portion of the second portion 142 is etched by using the second patterned metal layer 151 and the second patterned hard mask 161 as a second etching mask, thereby forming a semiconductor layer 145 below the second patterned metal layer 151. In other words, the passivation layer 180 and the second part 148 of the semiconductor material 140 are removed to form a third trench 123 next to the first part 147 of the semiconductor material 140. In some embodiments, a depth D1 of the second trench 122 (shown in FIG. 7) is at least greater than half of a depth D2 of the third trench 123. In some embodiments, the semiconductor layer 145 has a uniform width. In some embodiments, a width W5 of the semiconductor layer 145 is the same with a width W2 of the second patterned metal layer 151. At this time the second patterned metal layer 151, the second patterned hard mask 161, and the semiconductor layer 145 constitute a second bit line structure 174. In some embodiments, the semiconductor layer 145 is spaced apart from the insulating layer 130 in the trench 120 by a distance in the X-direction. That is to say the semiconductor layer 145 and the insulating layer 130 in the trench 120 are not in contact with each other in the X-direction. In some embodiments, the first bit line structure 172 and the second bit line structure 174 are alternately disposed on the substrate 110 at intervals. The two-step etching step reduces the possibility of necking profile occurs in the semiconductor layer. The present disclosure is not limited thereto, for example, the three-step etching step or multiple etching steps may be performed on the bit line structure with high aspect ratio. It should be understood that since a portion of the surface of the semiconductor material are protective by the passivation layer 180, the probability of undesirable necking profile may be reduced.

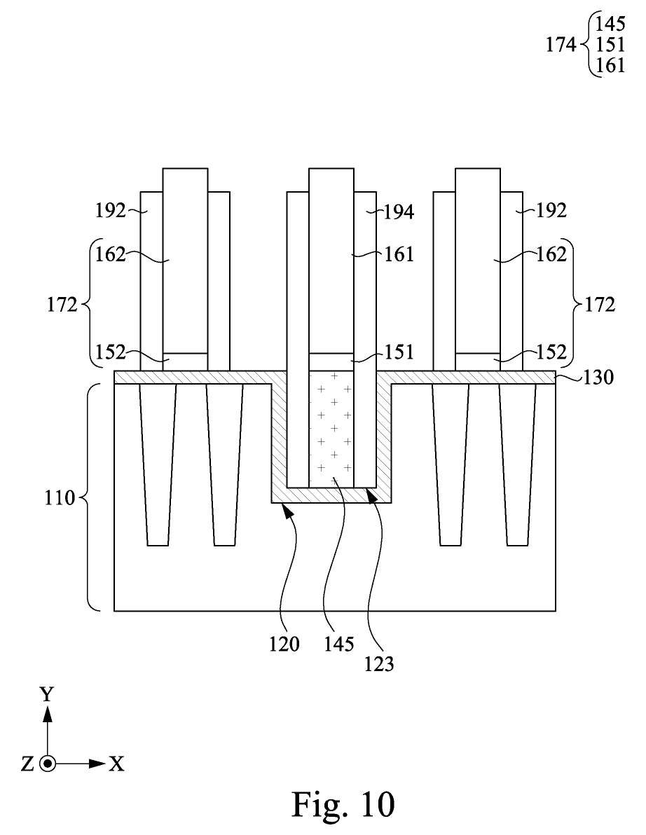

Referring to FIG. 10, a first spacer 192 is formed on a sidewall of the first bit line structure 172 and a second spacer 194 is formed on a sidewall of the second bit line structure 174. Particularly, the first spacer 192 extends along a sidewall of the first bit line structure 172 and the second spacer 194 extends along a sidewall of the second bit line structure 174. In other words, the first spacer 192 and the second spacer 194 extend along a vertical direction substantially perpendicular to the substrate 110 (e.g., along Z direction). In some embodiments, each of the first spacer 192 and the second spacer 194 may be a multi-layer structure made of any suitable dielectric materials. For example, the each of the first spacer 192 and the second spacer 194 may be a three-layer structure or a four-layer structure. In some embodiments, the material of the first spacer 192 may include oxide (such as silicon oxide), nitride (such as silicon nitride), and/or a combination thereof. In some embodiments, an air gap may be introduced into a confined space within the first spacer 192 and/or the second spacer 194 for the air gap with a dielectric constant of approximate 1 reducing parasitic capacitance.

In some embodiments, the first spacer 192 and the second spacer 194 may be formed by any suitable deposition approaches such as chemical vapor deposition (CVD) techniques, atomic layer deposition (ALD), or physical vapor deposition (PVD) techniques. In some embodiment, any suitable etching approaches such as reactive ion etching (RIE) techniques may be implemented on the first spacer 192 and the second spacer 194 to form a particular configuration depending on a design of a semiconductor device. For example, each layer in the multi-layer structure may not be the same high.

In some embodiments, the first spacer 192 covers the sidewalls of the first patterned metal layer 152 and a portion of the sidewall of the first patterned hard mask 162 as shown in FIG. 10. That is to say a top surface of the first patterned hard mask 162 is higher than a top surface of the first spacer 192. In alternative embodiments, the first spacer 192 completely covers the sidewalls of the first bit line structure 172. In other words, a top surface of the first patterned hard mask 162 is leveled with a top surface of the first spacer 192.

In some embodiments, the second spacer 194 covers the sidewalls of the second patterned metal layer 151 and the semiconductor layer 145 and covers a portion of the sidewall of the second patterned hard mask 161 as shown in FIG. 10. That is to say a top surface of the second patterned hard mask 161 is higher than a top surface of the second spacer 194. In alternative embodiments, the second spacer 194 completely covers the sidewalls of the second bit line structure 174. In other words, a top surface of the second patterned hard mask 161 is leveled with a top surface of the second spacer 194. In some embodiments, a height of the second spacer 194 is greater than a height of the first spacer 192 in the Y direction. It is noted that the second spacer 194 would fill up the remaining space in the trench 120. In other words, the second spacer 194 would be in direct contact with the semiconductor layer 145 and in direct contact with the insulating layer 130 in the trench 120. That is to say that the second spacer 194 is formed in the third trench 123.

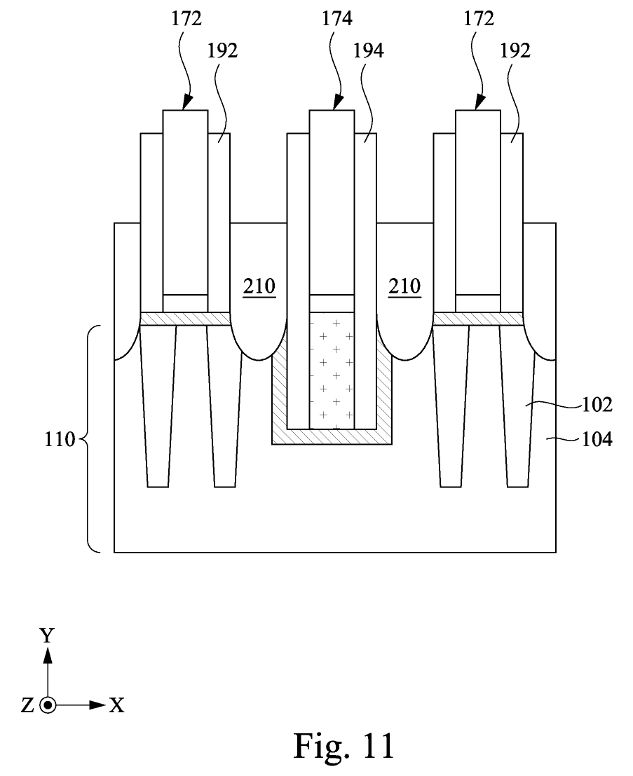

Referring to FIG. 11, a buried contact 210 (as the buried contact BC in FIG. 1) formed between adjacent the first bit line structure 172 and the second bit line structure 174. The buried contact 210 protrudes into the substrate 110 along the Z direction and directly contacts the portion of the active area 104. In some embodiments, the buried contact 210 has a plug-shaped structure and may be regarded as a contact plug structure. To be specific, the buried contact 210 is disposed between the first spacer 192 and the second spacer 194. The buried contact 210 includes a silicon-containing material. In some embodiments, the buried contact 210 may include doped polysilicon.

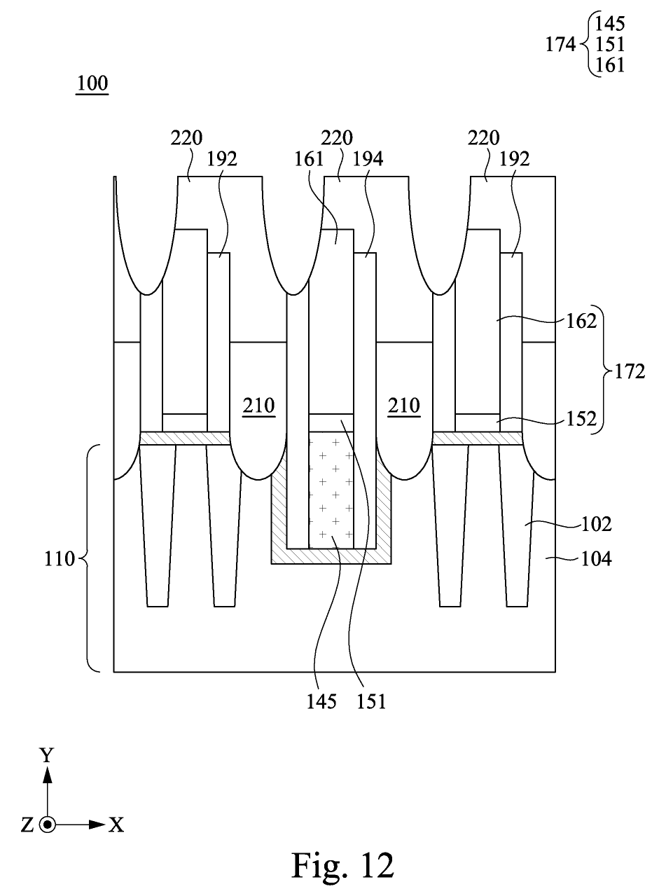

Referring to FIG. 12, a landing pad 220 (as the landing pad LP in FIG. 1) is formed on the first bit line structure172 and the second bit line structure 174 and further between the first bit line structure172 and the second bit line structure 174. The landing pad 220 may cover the first bit line structures 172, including a portion of the sidewalls of the first bit line structure 172 and a portion of a top surface of the first bit line structure 172. Similarly, the landing pad 220 may cover the second bit line structures 174, including a portion of the sidewalls of the second bit line structure 174 and a portion of a top surface of the second bit line structure 174. In some embodiments, the landing pad 220 may be stacked with materials including metal nitride or metal such as tungsten, tungsten nitride, and/or titanium nitride.

The above embodiments provide various advantages. The embodiments according to the disclosure disclose a method for manufacturing the semiconductor structure, which uses repeatedly etching (or multiple etching) steps of the semiconductor material instead of the traditional one-off etching to prevent the risk of necking of the bit line structure. In addition, nitrogen gas is introduced during multiple etching processes to form the passivation layer to strengthen a portion of the semiconductor layer from being affected by side etching.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method for manufacturing a semiconductor structure, comprising:
recessing a substrate from an upper surface of the substrate toward a lower surface of the substrate to form a trench;
filling a semiconductor material in the trench;
forming a patterned metal layer on the semiconductor material and forming a patterned hard mask on the patterned metal layer;
etching a portion of the semiconductor material by using the patterned metal layer and the patterned hard mask as a first etching mask, wherein a remaining portion of the semiconductor material comprises a first portion and a second portion below the first portion, and the second portion is wider than the first portion;
forming a passivation layer on a sidewall of the first portion; and
removing the passivation layer and etching the second portion of the remaining portion of the semiconductor material by using the patterned metal layer and the patterned hard mask as a second etching mask, thereby forming a semiconductor layer.

2. The method for manufacturing the semiconductor structure of claim 1, wherein forming the passivation layer on the sidewall of the first portion comprises reacting a nitrogen gas with the first portion.

3. The method for manufacturing the semiconductor structure of claim 1, wherein the passivation layer comprises nitride.

4. The method for manufacturing the semiconductor structure of claim 1, wherein a thickness of the passivation layer is from about 2.0 nm to about 5.0 nm.

5. The method for manufacturing the semiconductor structure of claim 1, wherein a height of the first portion of the semiconductor material is at least greater than half of a total height of the semiconductor material.

6. The method for manufacturing the semiconductor structure of claim 1, wherein the semiconductor layer has a uniform width.

7. The method for manufacturing the semiconductor structure of claim 1, wherein a width of the semiconductor layer is the same with a width of the patterned metal layer.

8. The method for manufacturing the semiconductor structure of claim 1, further comprising:
before filling the semiconductor material in the trench, conformally forming an insulating layer in the trench and on the upper surface of the substrate.

9. The method for manufacturing the semiconductor structure of claim 8, further comprising:
forming a spacer on sidewalls of the semiconductor layer, the patterned metal layer, and the patterned hard mask.

10. The method for manufacturing the semiconductor structure of claim 9, wherein the spacer is in direct contact with the semiconductor layer and is in direct contact with the insulating layer in the trench.

11. A method for manufacturing a semiconductor structure, comprising:
recessing a substrate from an upper surface of the substrate toward a lower surface of the substrate to form a first trench;
filling a semiconductor material in the first trench;
forming a patterned metal layer on the semiconductor material and forming a patterned hard mask on the patterned metal layer, wherein the semiconductor material comprises a first part covered by the patterned metal layer and the patterned hard mask and a second part next to the first part;
partially removing the second part of the semiconductor material to form a second trench;
forming a passivation layer to cover a sidewall of the first part; and
removing the passivation layer and the second part of the semiconductor material to form a third trench next to the first part of the semiconductor material.

12. The method for manufacturing the semiconductor structure of claim 11, wherein forming the passivation layer to cover the sidewall of the first part comprises reacting a nitrogen gas with the first part.

13. The method for manufacturing the semiconductor structure of claim 12, wherein reacting the nitrogen gas with the first part is performed under a temperature of 50°C to 70°C.

14. The method for manufacturing the semiconductor structure of claim 11, wherein the passivation layer comprises nitride.

15. The method for manufacturing the semiconductor structure of claim 11, wherein a thickness of the passivation layer is from about 2.0 nm to about 5.0 nm.

16. The method for manufacturing the semiconductor structure of claim 11, wherein a depth of the second trench is at least greater than half of a depth of the third trench.

17. The method for manufacturing the semiconductor structure of claim 11, wherein the third trench has a uniform width.

18. The method for manufacturing the semiconductor structure of claim 11, further comprising:
forming a spacer in the third trench.

19. The method for manufacturing the semiconductor structure of claim 11, further comprising:
before filling the semiconductor material in the first trench, conformally forming an insulating layer in the first trench and on the upper surface of the substrate.

20. The method for manufacturing the semiconductor structure of claim 19, wherein the insulating layer is exposed from the third trench.
